(19) United States
(12) Patent Application Publication
(10) Pub. No.: US 2013/0089948 A1
(43) Pub. Date: Apr. 11, 2013

(54) VAPOR TRANSPORT DEPOSITION METHOD AND SYSTEM FOR MATERIAL CO-DEPOSITION

(71) Applicant: First Solar, Inc., Perrysburg, OH (US)

(72) Inventors: Gang Xiong, Perrysburg, OH (US); John Barden, Ottawa Hills, OH (US)

(73) Assignee: First Solar, Inc., Perrysburg, OH (US)

(21) Appl. No.: 13/633,664

(22) Filed: Oct. 2, 2012

Related U.S. Application Data
(60) Provisional application No. 61/543,627, filed on Oct. 5, 2011.

(51) Int. Cl. H01L 21/365; B05B 1/24

(52) U.S. Cl. 438/102; 239/136; 257/E21.463

(57) ABSTRACT

An improved feeder system and method for vapor transport deposition that includes at least two vaporizers couple to a common distributor for vaporizing and co-depositing at least any two vaporizable materials as a material layer on a substrate. Composition of the material layer can be controlled by changing the flow of vapors from the respective vaporizers into the distributor to adjust the proportion of respective vapors in the combined vapor prior to deposition. Flow of the vapors from the respective vaporizers into the distributor may be controlled by adjusting the flow of carrier gas transporting the raw material into the vaporizer and/or by adjusting the vibration speed and/or amplitude of the powder feeders that process the raw material.

### FIELD OF THE INVENTION

Disclosed embodiments relate to the field of material vapor transport deposition (VTD) methods and systems, and more particularly to a material vapor transport deposition method and system which permits a controlled co-deposition of different materials.

### BACKGROUND OF THE INVENTION

Photovoltaic devices such as photovoltaic modules or cells, can include semiconductor and other materials deposited over a substrate using various deposition systems and techniques. One example is the deposition of a semiconductor material such as cadmium sulfide (CdS) or cadmium telluride (CdTe) thin films over a substrate using a VTD system. A VTD system may use a powder delivery unit, a powder vaporizer and vapor distributor, and a vacuum deposition unit.

VTD powder vaporizers are designed to vaporize or sublimate raw material powder into a gaseous form. In conventional powder vaporizers, raw material powder combined with a carrier gas is injected into a permeable heated cylinder from a powder delivery unit. The material is vaporized in the cylinders and the vaporized material diffuses through the permeable walls of the vaporizer into the distributor. The distributor collects and directs the flow of vaporized raw material for deposition as a thin film layer on a substrate. The distributor typically surrounds the vaporizer cylinder and directs collected vapors towards openings which face towards a substrate.

FIG. 1A illustrates one example of a conventional vapor transport deposition system 20 for delivering and depositing a semiconductor material, for example CdTe onto a substrate 13, for example, a glass substrate 13 used in the manufacture of thin film solar modules. Inert carrier gas sources 25 and 27, for example, Helium gas (He) sources, respectively provide a carrier gas to powder feeders 21 and 23, which contain CdTe powder material. The gas transports the semiconductor material through injector ports 17, 19 on opposite ends of a vaporizer and distributor assembly 10. The vaporizer and distributor assembly 10 vaporizes the semiconductor material powder and distributes it for deposition onto substrate 13.

FIG. 1B is a cross-sectional view, taken along the section line 2-2 of FIG. 1A, of one example of a conventional powder vaporizer and distributor assembly 10. The vaporizer 12 is constructed as a heated tubular permeable member. It is formed of a resistive material which can be heated by the electric power source 29 and vaporizes CdTe semiconductor material powder transported by the carrier gas into vaporizer 12 through injection ports 17, 19. The distributor 15 is formed of a thermal-conductive material, for example, graphite or an insulator, for example, mullite, which is heated by radiant heat from vaporizer 12. The distributor 15 surrounds vaporizer 12 to capture CdTe semiconductor material vapor that diffuses through the walls of vaporizer 12. CdTe semiconductor material vapor is directed by distributor 12 towards a slot or series of holes 14 which face a surface of substrate 13. More detailed examples of VTD systems of the type illustrated can be found in U.S. Pat. Nos. 5,945,163, 5,945,165, 6,037,241, and 7,780,787, all assigned to First Solar, Inc.

It may be desirable for certain deposition methods to introduce a dopant into the semiconductor material which can react with semiconductor material and form a vapor phase compound within vaporizer 12 during the deposition process. For example, CdTe semiconductor material powder and Si dopant powder can be combined as a Si—CdTe powder mixture with a predetermined blending concentration and loaded into powder feeders 21 and 23. The Si—CdTe powder mixture is then introduced into vaporizer and distributor assembly 10 for chemical reaction and co-vaporization. After diffusion through vaporizer 12, the mixture of vapors is captured in the vapor housing 15 and directed through holes 14 for deposition as a thin film layer on substrate 13. The vaporization of the Si—CdTe powder mixture does not allow for composition control of the predetermined blending concentration of the Si—CdTe powder mixture unless the vapor transport deposition system 20 is stopped, the dopant/semiconductor powder mixture is removed from powder feeders 21 and 23 and an alternate dopant/semiconductor powder mixture is loaded. This complete shut-down of the VTD system for adjustment in the blending concentration of the dopant/semiconductor powder mixture is time consuming and costly.

An improved vapor transport deposition system which mitigates against the noted problems is desirable.

### BRIEF DESCRIPTION OF THE DRAWINGS

FIG. 1A is a schematic of a conventional vapor transport deposition (VTD) system;

FIG. 1B is a cross-sectional view taken along the direction of line 2-2 in FIG. 1A to illustrate an example of a conventional powder vaporizer and distributor assembly;

FIG. 2 is a schematic of an embodiment of a vapor transport deposition (VTD) system;

FIG. 3 is a cross-sectional view taken along the direction of line 4-4 in FIG. 2 to illustrate an example of the FIG. 2 vaporizer and distributor assembly embodiment;

FIG. 4 is a bottom plain view taken along the direction of line 5-5 of FIG. 3 to illustrate a varying size slit opening of the apparatus;

FIG. 5A illustrates a method 100 for depositing multiple materials in combination as a layer on a substrate using a VTD system with a vaporizer and distributor assembly;

FIG. 5B illustrates a further outline of steps 109 and 110 from method 100 of using the vaporizer units to vaporize material powder;

FIG. 5C illustrates a further outline of steps 111 and 112 from method 100 of passing material vapors from the vaporizers into the vapor distributor; and

FIG. 5D illustrates a further outline of step 114 from method 100 of adjusting the composition of the combined material vapor.

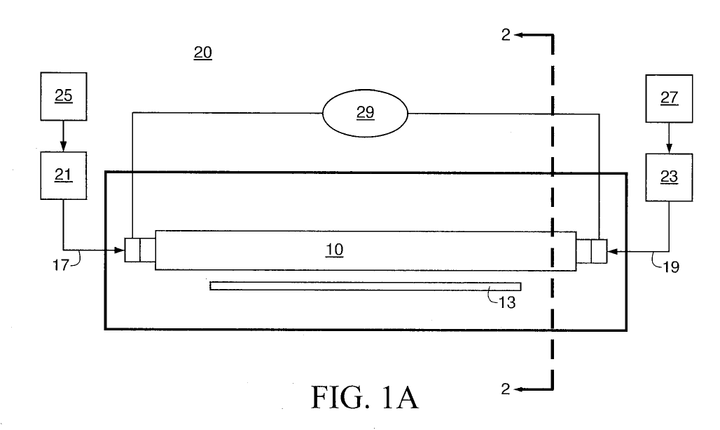

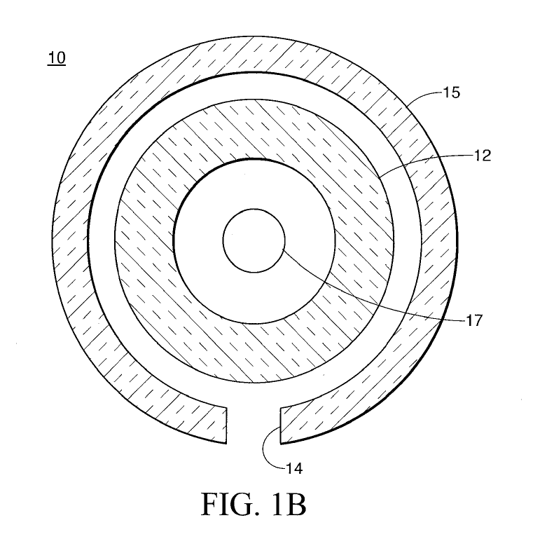

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

According to one example embodiment, an improved vapor transport deposition method and system are provided which include a distributor coupled to two vaporizers. The distributor may employ a thermal conductive material and be heated by radiant heat from the two vaporizers. Each respective vaporizer can independently vaporize or sublimate a different raw material powder into a respective raw material vapor and the two vapors may diffuse out of the respective vaporizers into a common chamber within the distributor. The two raw material vapors combine within the distributor chamber and the combined vapor is directed out of the distributor chamber for deposition on a substrate as a thin film layer composed of multiple materials. This example embodiment may further include at least two powder feeders for providing at least two different vaporizable powders to the respective vaporizers. A first powder feeder may be loaded with a first vaporizable material and a second powder feeder may be loaded with a different second vaporizable material. At least two carrier gas sources may provide a carrier gas, for example Helium (He), into respective powder feeders to transport the respective vaporizable material powders from the powder feeders into the respective vaporizers.

The concentration balance of the compounds in the combined vapor may be determined and altered by adjusting the flow of vapor from one and/or both of the respective vaporizers into the distributor. Flow of the vapor into the respective distributor is controlled by adjusting material flow rates at other points in the VTD system. For example, vapor flow may be controlled by adjusting vibration speed and amplitude of the powder feeders that process the raw material into a powder form. The flow of vapor may also be controlled by adjusting the flow rate of the carrier gas, for example Helium gas, that transports the raw material from the respective powder feeders into the respective vaporizers. These adjustments control raw material flow into the vaporizer, and correspondingly control the flow of vapor from the respective vaporizer into the common distributor chamber. Therefore, the relative amount of raw material from the respective vaporizer in the vapor mixture can be controlled to alter the ultimate thin film layer composition. This independent control of the raw material vapor from the respective vaporizer into the distributor allows for easy control of the composition of the combination vapor without a shut-down of the vapor transport deposition system.

This improved vapor transport deposition method and system can be used to deposit a single vaporizable material that is loaded into both vaporizers. For deposition of a single vaporizable material, independent control of the raw material vapor from multiple vaporizers allows for system redundancy. A single vaporizer can continue to operate if components of the second vaporizer malfunction and must be repaired. This maintains continual production during repair or component replacement.

This improved vapor transport deposition method and system can also be used to co-deposit any two or more vaporizable materials or combinations of vaporizable materials. For example, the various vaporizable materials may include but are not limited to combinations of multiple semiconductor materials, semiconductor alloys, a semiconductor material and a dopant, or multiple semiconductor materials and/or dopant. Vaporizable semiconductor materials may, for example, include copper indium gallium selenide (CIGS) or a transition metal (Group 12) combined with a chalcogenide (Group 18) such as cadmium telluride (CdTe), cadmium sulfide (CdS), zinc telluride (ZnTe) or zinc sulfide (ZnS). Suitable vaporizable dopants may include Si, CuCl₂ or MnCl₂. Suitable semiconductor alloys may include CdₓZn₁₋ₓTe, CdTeₓS₁₋ₓ, or phase change material such as GeSbTe.

In one exemplary use of the embodiment described above, cadmium telluride (CdTe) is co-deposited with a Si dopant as a semiconductor thin layer. A first powder feeder may be loaded with cadmium telluride (CdTe) and a second powder feeder may be loaded with a concentrated Si:CdTe powder mix as a dopant. The CdTe semiconductor material powder and the concentrated Si:CdTe dopant powder are delivered by the respective powder feeders to the respective vaporizers. The CdTe material is vaporized to form Cd(g) and Te(g) and the concentrated Si:CdTe dopant mixture reacts and is vaporized to form SiTex(g), Cd(g) and Te(g). The Cd(g), Te(g) and SiTex(g) diffuse through the respective vaporizers and combine in the common distributor chamber to form a mixture of all three gasses, which is directed out of the distributor for co-deposition as a thin film layer on a substrate. In this example, independent control of the vapor flow from the respective vaporizers allows for composition control of the mixture of Cd(g), Te(g) and Si(g) to ensure optimal production of SiTe_{X} (gas) without the need for time consuming and costly VTD system shut-downs to adjust powder composition balance.

In another example use of the embodiment described above, cadmium telluride (CdTe) is co-deposited with zinc telluride (ZnTe) to form a semiconductor alloy thin layer. A first powder feeder may be loaded with cadmium telluride (CdTe) and a second powder feeder may be loaded with zinc telluride (ZnTe). The CdTe semiconductor material powder and the ZnTe semiconductor material powder are delivered by the respective powder feeders to the respective vaporizers. The CdTe material is vaporized to form Cd(g) and Te(g) and the ZnTe material is vaporized to form Zn(g) and Te(g). The Cd(g), Te(g) and Zn(g) diffuse through the respective vaporizers and combine in the common distributor chamber to form a mixture of gasses. The mixture of gasses is directed out of the distributor for deposition as a CdₓZn₁₋ₓTe thin film alloy layer on a substrate. Independent control of the vapor flow from the respective vaporizers allows for composition control of the mixture of Cd(g), Te(g) and Zn(g) to ensure optimal composition of the CdₓZn₁₋ₓTe thin film alloy layer without excess reactants.

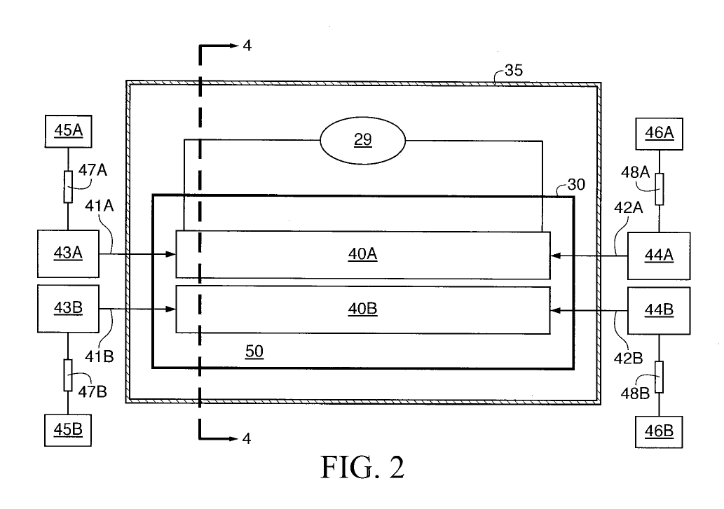

FIG. 2 illustrates an embodiment of a deposition system for delivering and depositing multiple vaporizable materials in combination onto a substrate 13 (not shown), for example, a glass substrate used in the manufacture of thin film solar modules. The deposition system includes a vaporizer and distributor assembly 30, which is housed within a vacuum vessel 35. Vaporizer and distributor assembly 30 includes a pair of vaporizer units 40a, 40b coupled to a distributor unit 50 and having vaporizer inlets 41a, 42a and 41b, 42b at opposite ends for receiving vaporizable material powders from respective material feeders 43a, 43b and 44a, 44b. Inert carrier gas sources 45a, 46a, and 45b, 46b, for example Helium gas (He) sources, respectively provide a carrier gas to material feeders 43a, 43b and 44a, 44b through mass flow controllers 47a, 47b and 48a, 48b to transport the raw material through respective vaporizer inlets 41a, 42a and 41b, 42b into respective vaporizer units 40a, 40b. Mass flow controllers 47a, 47b and 48a, 48b regulate the flow of carrier gas through respective material feeders 43a, 43b and 44a, 44b, which controls the flow rate of semiconductor material powder into respective vaporizer units 40a, 40b and the flow rate of vaporizable material vapor into distributor unit 50.

Material feeders 43a, 43b and 44a, 44b may be any type of material supplier that can be utilized for processing the raw material into a powder form and feeding the material powder into the vaporizer and distributor assembly 30, for example, vibratory powder feeders, fluidized bed feeders and rotary disk feeders that are commercially available. As described above, the vibration speed and/or amplitude used to process the raw material into the powder form can control flow of raw material from material feeders 43a, 43b and 44a, 44b through respective vaporization units 40a, 40b and to the vaporizer and distributor assembly 30. The vibration speed and/or amplitude of the material feeders 43a, 43b and 44a, 44b may be adjusted by a manual input or a digital/analog signal.

The inert carrier gases input from inert carrier gas sources 45a, 46a, and 45b, 46b can alternatively be another inert gas such as nitrogen, neon, argon or krypton, or combinations of these gases. It is also possible for the carrier gas to be mixed with and include some amount of a reactive gas such as oxygen that can advantageously affect growth properties of the material. A flow rate of about 0.0001 to about 10 slpm of the carrier gas has been determined to be sufficient to facilitate flow of the powder out of material feeders 43a, 43b and 44a, 44b, through vaporization units 40a, 40b and through the vaporizer and distributor assembly 30. Mass flow controllers 47a, 47b, 48a, 48b may adjust flow rate between about 0.0001 to about 10 slpm during the deposition process to control substrate composition.

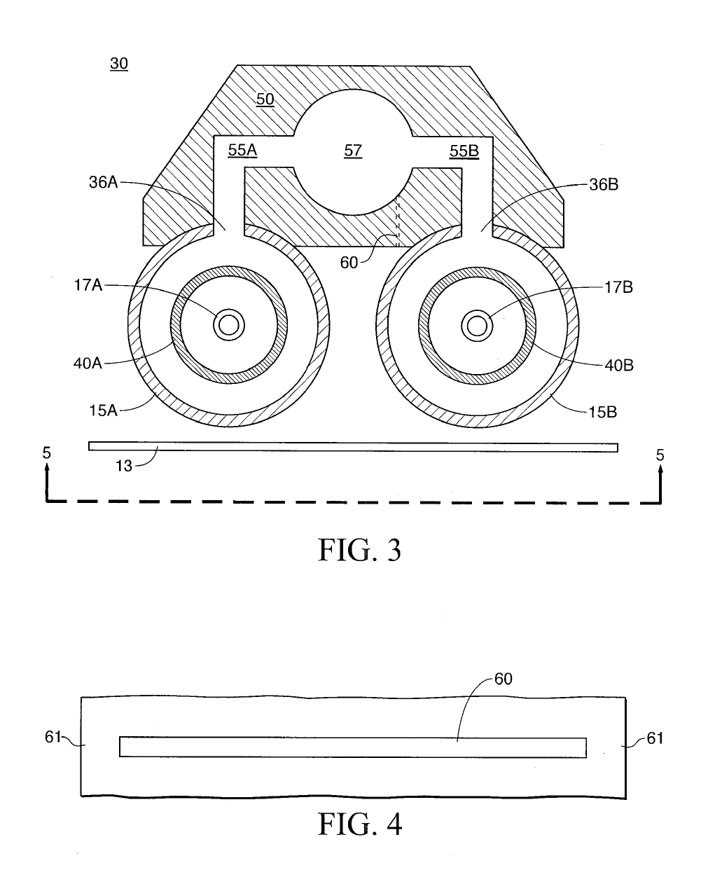

FIG. 3 illustrates a cross sectional view of the vaporizer and distributor assembly 30 in FIG. 2, taken along the section line 4-4. As shown in FIG. 3, vaporizer units 40a, 40b are enclosed within and coupled to the common distributor unit 50. Vaporizer units 40a, 40b are comprised respectively of permeable tubular walls, which are formed of a resistive material heated by electric power 29 and which vaporize material powder carried by an inert gas, e.g. Helium gas (He) from inlets 41a, 41b, 42a, 42b through respective injection ports 17a, 17b. Distributor unit 50 comprises respective vapor housings 15a, 15b, formed of a thermal-conductive material, for example, graphite, or insulator, for example, mullite, which may be heated by radiant heat from vaporizers 40a and 40b. Respective vapor housings 15a, 15b enclose respective vaporizer units 40a, 40b to capture material vapor that diffuses through the permeable tubular walls of vaporizer units 40a, 40b. Semiconductor material vapor is directed within the respective vapor housings 15a, 15b through respective channels 55a, 55b to a common distributor chamber 57 in distributor unit 50. Semiconductor material vapors from respective vaporizer units 40a, 40b combine in the common distributor chamber 57 and the combination material vapor is directed towards a single opening 60 or a plurality of openings 60 which direct the combination material vapor out of the distributor unit 50 to be deposited onto a substrate 13.

The vaporizer units 40a, 40b are made of any permeable material that is preferably electrically conductive, such as silicon carbide, and heated by electric power 29 to provide for vaporization or sublimation of material. Furthermore, the vapor housings 15a, 15b are generally a tubular shape that encloses the vaporizer units 40a, 40b as illustrated in FIG. 3. As described above, the vapor housings 15a, 15b direct the vapor material toward respective openings 36a, 36b through which the vapor passes into distributor chamber 57 through respective channels 55a, 55b where the vapors mix prior to deposition.

The distributor unit 50 is heated by radiant heat from vaporizers 40a and 40b, which can be powered by electricity. Vaporizers 40a and 40b provide radiant heat to the surface of distributor unit 50 sufficient to maintain a temperature up to about 1350° C. in the distributor chamber 57. Vapor pressure within distributor chamber 57 is between about 1 to about 10 Torr.

The single opening 60 or the plurality of openings 60 for directing the combination material vapor out of the distributor chamber 57 are preferably constructed as slit-shaped or circular openings, which can have a uniform width, as more clearly shown in FIG. 4, or non-uniform width between opposite ends 61. More specifically, a single opening 60, as shown in FIG. 4, may extend along the base of the distributor unit 50 between and parallel to vapor housings 15a, 15b or a plurality of openings 60 as shown in FIG. 4, may extend along the base of the distributor unit 50 between and parallel to vapor housings 15a, 15b, each opening 60 being parallel to all other openings 60. The openings 60 may be selected to control the extent of the width of the deposited layer on the substrate 13 by making the length of the opening 60 less than the corresponding length of the substrate 13 beneath opening 60.

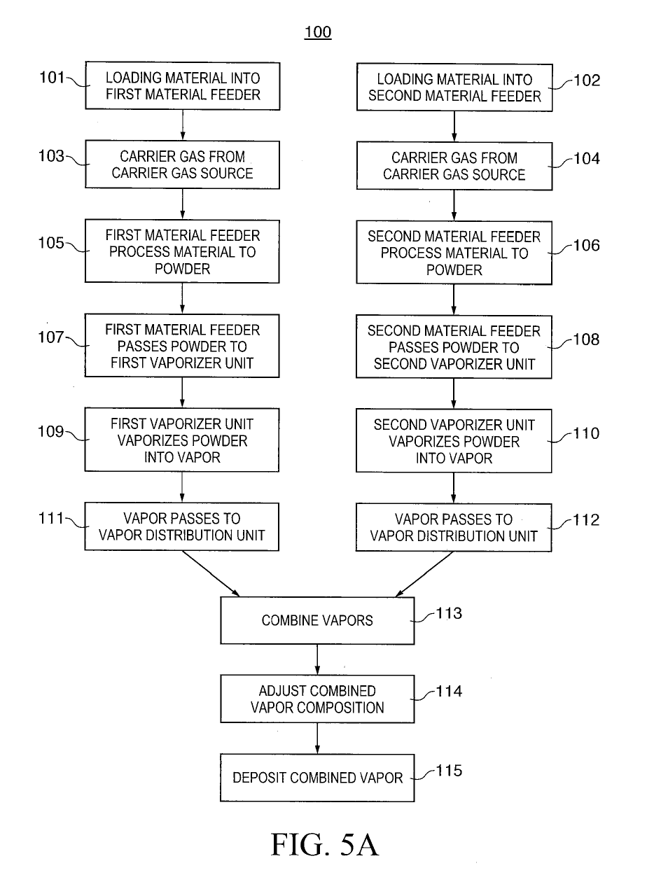

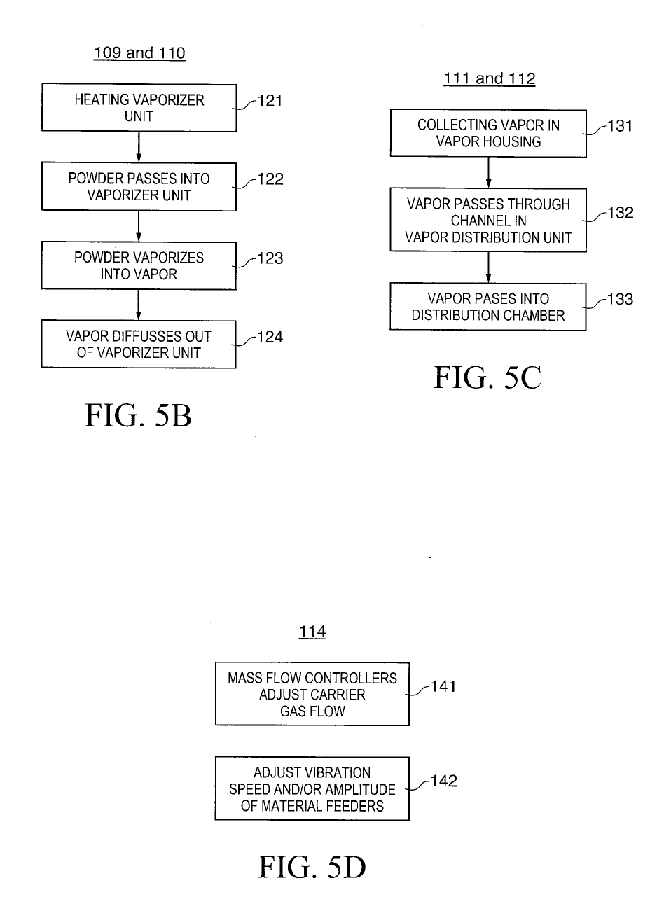

A method 100 for depositing multiple materials in combination as a layer on a substrate using a VTD system with a vaporizer and distributor assembly as described herein, is shown in FIG. 5A. As described above, multiple material feeders are used to process material into powder and feed it into the vaporizer units of the vaporizer and distributor assembly. In method 100, steps 101, 103, 105, 107, 109 and 111 pertain to using a first material feeder to provide vaporizable material through a first inlet into a first vaporizer unit. Steps 102, 104, 106, 108, 110 and 112 pertain to using a second material feeder to provide a different vaporizable material through a second inlet into a second vaporizer unit. Though not described as separate steps of method 100 or shown in FIG. 5A, at least two additional material feeders, as shown in FIG. 2, may be used as needed to process and feed additional material into third and/or forth inlets on opposite ends of the first and second vaporizer units of the vaporizer and distributor assembly by following steps 100-112. At steps 101 and 102, material is loaded into the vibratory powder feeder of a first and/or second material feeder. At steps 103 and 104, respective carrier gas sources provide respective carrier gases to respective first and/or second material feeders. The respective material feeders are used to process the material into a powder at steps 105 and 106. At steps 107 and 108, the respective material feeders are used to pass the carrier gas and the material powder into respective vaporizer units. The respective vaporizer units are used to vaporize the respective material powder into respective material vapors at steps 109 and 110. At steps 111 and 112, the respective material vapors are passed from the respective vaporizer units into the common distributor unit. At step 113, the respective vapors are combined in the chamber of the distributor unit to form a combined material vapor. At step 114, the composition of the combined material vapor can be adjusted by varying the flow of the respective vapors from the respective vaporizer units into the distributor unit. At step 115, the distributor unit is used to deposit the combined material vapor onto a substrate.

The steps 109 and 110 of using the respective vaporizer units to vaporize the respective material powders into respective material vapors are further outlined in FIG. 5B. At step 121, vaporizer units are heated. At step 122, the respective material powders are passed into the respective vaporizer units with carrier gas. The respective material powders are vaporized into respective material vapors at step 123. At step 124, the respective material vapors diffuse through the permeable wall of the vaporizer unit to be collected and passed to the distributor unit.

The steps 111 and 112 of passing the respective material vapors from the respective vaporizers into the distributor unit are further outline in FIG. 5C. At step 131, respective material vapor is collected from respective vaporizer units using respective vapor housings. At step 132, the respective material vapors are passed from the respective vapor housings to respective channels in the distributor unit. The respective material vapors pass through the respective channels in the distributor unit to a distributor chamber at step 133.

The step 114 of adjusting the composition of the combined material vapor by adjusting the flow of the respective vapors from the respective vaporizer units into the distributor unit is further outlined in FIG. 5D. At step 141, the flow of the respective vapors from the respective vaporizer units can be adjusted by using respective mass flow controllers to adjust the flow of carrier gas through the respective material feeders. At step 142, the flow of the respective vapors from the respective vaporizer units can be varied by adjusting the vibration speed and/or amplitude of the respective material feeders. Either step 141 or 142 or both may be used to adjust the composition of material deposited on a substrate.

The system illustrated in FIGS. 2 and 3 and the method illustrated in FIGS. 5A, 5B, 5C and 5D may be used to vaporize and deposit a combination of from one to four different vaporizable materials provided in from one to four material feeders. For example, the various materials may include combinations of multiple semiconductor materials, a semiconductor material and a dopant, or multiple semiconductor materials and/or dopants. In one such embodiment, the deposition system illustrated in FIG. 2 can be used to vaporize and deposit a single semiconductor material loaded into each of material feeders 43a, 43b and 44a, 44b. In another embodiment, the deposition system can be used to vaporize and deposit one material loaded into each of material feeders 43a and 44a and a second material loaded into each of material feeders 43b and 44b. In this embodiment, the first and second material can both be semiconductor materials or one of the materials can be a semiconductor material and one of the materials can be a dopant. In a third embodiment, the deposition system can be used to vaporize and deposit a first material loaded into material feeder 43a, a second material loaded into material feeder 44a and a third material loaded into material feeder 43b. In this embodiment, material feeder 44b can remain idle during the vaporization and deposition process or can be loaded with the same material as material feeder 43b. Again, the materials can be any combination of semiconductor materials and/or dopants. In a fourth embodiment, the deposition system can be used to vaporize and deposit four materials, each loaded into a respective material feeders 43a, 43b, 44a, and 44b.

It should be noted that since the deposition system illustrated in FIGS. 2 and 3 and the method illustrated in FIGS. 5A, 5B, 5C and 5D can be used to co-deposit any two or more vaporizable materials, the system and method can be used to form various layer compositions. For example, the deposition system illustrated in FIGS. 2 and 3 and the method illustrated in FIGS. 5A, 5B, 5C and 5D can be used to vaporize CdTe and CdS for combination and co-deposition as a layer of CdTe₁₋ₓSₓ alloy. In another example, CdTe and ZnTe may be vaporized and combined to be co-deposited as a layer of CdₓZn₁₋ₓTe alloy. In another example, CdS and ZnS may be vaporized and combined to be deposited as a layer of CdZn₁₋ₓSₓ alloy.

While embodiments have been described in detail, it should be readily understood that the invention is not limited to the disclosed embodiments. Rather the embodiments can be modified to incorporate any number of variations, alterations, substitutions, or equivalent arrangements not heretofore described without departing from the spirit and scope of the invention.

What is claimed as new and desired to be protected by Letters Patent of the United States is:

1. An apparatus comprising:
a first vaporizer unit for vaporizing a first powder material;
a second vaporizer unit for vaporizing a second powder material; and,
a vapor distribution unit for combining the vapor outputs from the first and second vaporizer units and for providing a combined vapor at an output.

2. The apparatus of claim 1, wherein the first vaporizer unit further comprises:
a first permeable tubular member having at least one material inlet port for receiving the first powder material; and,
wherein the second vaporizer unit further comprises:
a second permeable tubular member having at least one material inlet port for receiving the second powder material.

3. The apparatus of claim 2, wherein the vapor distribution unit further comprises:
a first vapor housing for capturing material vapor from the first permeable tubular member;
a second vapor housing for capturing material vapor from the second permeable tubular member;
a chamber for combining the material vapors captured by the first and second vapor housings; and,
a chamber outlet for deposition of the combined vapor.

4. The apparatus of claim 3, wherein the vapor distribution unit comprises a thermal-conductive material.

5. The apparatus of claim 4, wherein the vapor distribution unit comprises graphite.

6. The apparatus of claim 4, wherein the vapor distribution unit comprises a thermal-conductive block.

7. The apparatus of claim 2, wherein the first and second vapor housings comprise a thermal-conductive material.

8. The apparatus of claim 2, wherein the first and second vapor housings comprise graphite.

9. The apparatus of claim 3 further comprising first and second vibration powder feeders for respectively feeding said first and second powder materials into respective first inlet ports of the first and second vaporizer units.

10. The apparatus of claim 9 further comprising third and forth vibration powder feeders for respectively feeding said first and second powder materials into respective second inlet ports of the first and second vaporizer units.

11. The apparatus of claim 9, wherein at least one of said first and second powder materials is a semiconductor powder material.

12. The apparatus of claim 9, wherein said first powder material is a semiconductor material and said second powder material is a dopant.

13. The apparatus of claim 11, wherein the semiconductor powder material is CdTe.

14. The apparatus of claim 11, wherein the first semiconductor powder material is CdTe and the second semiconductor powder material is CdS.

15. The apparatus of claim 11, wherein the first semiconductor powder material is CdTe and the second semiconductor powder material is ZnTe.

16. The apparatus of claim 11, wherein the first semiconductor powder material is CdTe and the second semiconductor powder material is ZnS.

17. The apparatus of claim 12, wherein the first powder material is CdTe and the dopant comprises Si.

18. The apparatus of claim 12, wherein the first powder material is CdTe and the dopant comprises CuCl₂.

19. The apparatus of claim 12, wherein the first powder material is CdTe and the dopant is MnCl₂.

20. The apparatus of claim 10, wherein at least one of said first and second powder materials is a semiconductor powder material.

21. The apparatus of claim 10, wherein said first powder material is a semiconductor material and said second powder material is a dopant.

22. A system comprising:
at least two vaporizers;
a first material feeder for directing material into the first vaporizer;
a second material feeder for directing material into the second vaporizer; and,
a distributor for combining the vapor outputs of the first and second vaporizers and providing a combined vapor output.

23. The system of claim 22 further comprising at least one mass flow controller for controlling the flow of material into at least one of said first and second vaporizers.

24. The system of claim 22 further comprising:
a first mass flow controller for controlling the flow of material into the first vaporizer; and,
a second mass flow controller for controlling the flow of material into the second vaporizer.

25. The system of claim 22; wherein at least one of the first and/or second material feeders are vibratory feeders having adjustable vibration frequency and/or amplitude for controlling the flow of material into at least one of said first and second vaporizers.

26. The system of claim 22 further comprising:
a third material feeder for directing material into the first vaporizer; and,
a fourth material feeder for directing material into the second vaporizer.

27. The system of claim 26 further comprising:
a first carrier gas source for directing a carrier gas through a first mass flow controller into the first material feeder;
a second carrier gas source for directing the carrier gas through a second mass flow controller into the second material feeder;
a third carrier gas source for directing the carrier gas through a third mass flow controller into the third material feeder; and,
a fourth carrier gas source for directing the carrier gas through a fourth mass flow controller into the fourth material feeder.

28. The system of claim 26, wherein the first and third material feeders are coupled to opposite ends of first vaporizer; and,
the second and fourth material feeders are coupled to opposite ends of the second vaporizer.

29. The system of claim 25, wherein the distributor further comprises:
a chamber for combining the material vapors into the combined vapor;
a first vapor housing for capturing the vapor that defuses out of the first vaporizer;
a second vapor housing for capturing the vapor that defuses out of the second vaporizer;
a first channel for connecting the first vapor housing to the chamber;
a second channel for connecting the second vapor housing to the chamber; and,
an output leading from the chamber out of the distributor for outputting the vapor.

30. The system of claim 29, wherein the distributor comprises a thermal-conductive material.

31. The system of claim 30, wherein the material provided by the material feeders is a semiconductor material.

32. The system of claim 28, wherein the material provided by the first and third material feeders is a first semiconductor material and the material provided by the second and fourth material feeders is a second semiconductor material.

33. The system of claim 28, wherein the material provided by the first and third material feeders is a first semiconductor material and the material provided by the second and fourth material feeders is a dopant.

34. The system of claim 31, wherein the semiconductor material comprises CdTe.

35. The system of claim 32, wherein at least one of the first and the second semiconductor materials comprises CdTe.

36. The system of claim 33, wherein the first semiconductor material comprises CdTe and the dopant comprises Si.

37. A method for depositing a material comprising:
vaporizing a first material powder into a first material vapor;
vaporizing a second material powder into a second material vapor;
combining the first material vapor and the second material vapor into a combined material vapor; and,
outputting the combined material vapor.

38. The method described in claim 37, further comprising:
passing the first material vapor from a first vaporizer unit into a vapor distribution unit; and,
passing the second material vapor from a second vaporizer unit into the vapor distribution unit.

39. The method described in claim 38, further comprising:
adjusting the composition of the combined material vapor by adjusting the flow of at least one of the first and second material powders.

40. The method described in claim 38, further comprising:
adjusting the composition of the combined material vapor by adjusting the flow of both the first and second material powders.

41. The method described in claim 40, further comprising:
adjusting the flow of the first and second material powders using a first and second mass flow controller to adjust the flow of carrier gas into the first and second material feeders.

42. The method described in claim 40, further comprising:
adjusting the flow of the first and second material powders by adjusting the vibration frequency and/or amplitude of the first and second material feeders.

43. The method of claim 37, wherein the step of combining the first material vapor and the second material vapor further comprises:
capturing the first material vapor from the first vaporizer unit in a first vapor housing;
passing the first material vapor from the first vapor housing to a chamber in the vapor distribution unit;
capturing the second material vapor from a second vaporizer unit in a second vapor housing;
passing the second material vapor from the second vapor housing to the chamber in the vapor distribution unit; and,
combining the material vapors from the first and second vaporizer units in the chamber.

44. The method of claim 39, wherein the step of adjusting the composition of the combined material vapor by adjusting the flow of material vapor from the first and/or second vaporizer units into the vapor distribution unit further comprises:
using mass flow controllers to adjust the flow of carrier gas which transports at least one of the first and second materials.

45. The method of claim 39, wherein the step of adjusting the composition of the combined material vapor by adjusting the flow of material vapor from the first and/or second vaporizer units into the vapor distribution unit further comprises:
using a vibratory material feeder to adjust the flow of at least one of the first and second materials into the first and second vaporizer units.

46. The method of claim 37, wherein at least one of the first and second material powders is a semiconductor material.

47. The method of claim 37, wherein the first material powder is a first semiconductor material and the second material powder is a different second semiconductor material.

48. The method of claim 37, wherein the first material powder is a first semiconductor material and the second material powder is a dopant.

49. The method of claim 46, wherein the semiconductor material is CdTe.

50. The method of claim 47, wherein at least one of the first and the second semiconductor materials is CdTe.

51. The method of claim 48, wherein the first semiconductor material is CdTe and the dopant is Si.

52. A method for controlling the composition of a combined material deposited on a substrate comprising:
passing a first vapor from a first vaporizer unit into a vapor distributor unit;
passing a second vapor from a second vaporizer unit into the vapor distributor unit;
using the vapor distributor unit to combine the first vapor and the second vapor as a combination vapor;
varying the amount of the first vapor in the combination vapor by varying flow of the first vapor into the vapor distributor unit;
varying the amount of the second vapor in the combination vapor by varying flow of the second vapor into the vapor distributor unit; and,
using the vapor distributor unit to deposit the combination vapor onto the substrate.

53. The method of claim 52, wherein the first and second vapors are a semiconductor material.

54. The method of claim 52, wherein the first vapor is a first semiconductor material vapor and the second vapor is a second semiconductor material vapor.

55. The method of claim 52, wherein the first vapor is a first semiconductor material vapor and the second vapor is a dopant.

56. The method of claim 53, wherein the semiconductor material is CdTe.

57. The method of claim 54, wherein at least one of the first and the second semiconductor materials is CdTe.

58. The method of claim 55, wherein the first semiconductor material is CdTe and the dopant is Si.
